(19) United States
(12) Patent Application Publication
(10) Pub. No.: US 2010/0248424 A1
(43) Pub. Date: Sep. 30, 2010

(54) Self-Aligned Chip Stacking

(75) Inventors: Stephen E. Luce, Underhill, VT (US); Anthony K. Stamper, Williston, VT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: Intellectual Business Machines Corporation, Armonk, NY (US)

(21) Appl. No.: 12/634,752

(22) Filed: Dec. 10, 2009

Related U.S. Application Data
(60) Provisional application No. 61/163,892, filed on Mar. 27, 2009.

(51) Int. Cl. H01L 21/78; H01L 21/98

(52) U.S. Cl. 438/109; 438/119; 438/113; 257/E21.705; 257/E21.599

(57) ABSTRACT

A first semiconductor chip and a second semiconductor chip are provided with a matching pair of hydrophilic top surfaces each including a matched set of conductive contact structures. In one embodiment, the first semiconductor chip, the second semiconductor chip, or both is provided with a mesa of which the periphery coincides with the shape of a hydrophilic top surface. In another embodiment, the first semiconductor chip, the second semiconductor chip, or both is provided with a peripheral hydrophobic top surface that laterally surrounds a hydrophilic top surface. Prior to vertical stacking, a polar liquid coats the hydrophilic top surface of a first semiconductor chip. When a second semiconductor chip is placed on the polar liquid, the matching shapes of two hydrophilic surfaces are self-aligned by moving the second semiconductor chip as needed.

### FIELD OF THE INVENTION

The present invention relates to methods of forming a semiconductor structure, and particularly to methods of stacking semiconductor chips in self-alignment.

### BACKGROUND OF THE INVENTION

Chip stacking refers to a method of assembling two or more semiconductor chips so that the semiconductor chips that are placed in physical proximity to one another are also electrically connected among one another. Chip stacking is typically performed vertically, i.e., one chip is placed above or below another chip. When two chips are brought together vertically, a set of conductive contact structures on the top surface of an underlying chip is aligned to another set of conductive contact structures on the bottom surface of an overlying chip. The conductive structures may be formed on the side of metal interconnect structures, or they may be formed on the side of a substrate on which semiconductor devices are formed.

Chip stacking may be performed between a substrate and a set of chips, or may be performed between pairs of chips. The alignment process employed to vertically stack two chips invariably induces some overlay variations. In some cases, such overlay variations may be in the range from 1 micron to 10 microns. Because proper operation of a stacked chip requires functional electrical connections between an underlying chip and an overlying chip, the overlay tolerance of the alignment process often determines the minimum lateral dimensions of conductive contact structures on both chips. The minimum lateral dimensions in turn determine the maximum density of contacts that may be formed between two stacked chips. While reducing overlay tolerance of the alignment process during chip stacking would enable high density contacts and reliability of stacked chips, such improvement requires investment in equipment and process control, and is thus costly and cumbersome.

### SUMMARY OF THE INVENTION

The present invention provides a method of self-aligning chips to be vertically stacked by providing a pair of hydrophilic surfaces that are located on a mesa or surrounded by hydrophobic surfaces.

In the present invention, a first semiconductor chip may be located in a substrate or may be provided as a stand-alone chip. A second semiconductor chip is provided as a stand-alone diced chip. The first semiconductor chip and the second semiconductor chip are provided with a matching pair of hydrophilic top surfaces each including a matched set of conductive contact structures. Preferably, the shapes of the matching pair of hydrophilic top surfaces are mirror images of each other. Preferably, the shapes of the matched set of conductive contact structures are mirror images of each other. In one embodiment, the first semiconductor chip, the second semiconductor chip, or both is provided with a mesa of which the periphery coincides with the shape of a hydrophilic top surface. In another embodiment, the first semiconductor chip, the second semiconductor chip, or both is provided with a peripheral hydrophobic top surface that laterally surrounds a hydrophilic top surface. Prior to vertical stacking, a polar liquid coats the hydrophilic top surface of a first semiconductor chip so that the edge of the polar liquid coincides with the edges of a mesa or an inner periphery of a peripheral hydrophobic top surface. When a second semiconductor chip is placed on the polar liquid, the matching shapes of two hydrophilic surfaces are self-aligned by moving the second semiconductor chip as needed. Once the polar liquid dried out, a self-aligned stack of a first and second semiconductor chips is formed.

According to an aspect of the present invention, a method of forming a semiconductor structure is provided. The method includes: providing a first semiconductor chip including a mesa and a first recessed peripheral region around the mesa, wherein the mesa has a first hydrophilic top surface, and wherein a first periphery of the mesa has a first shape; providing a second semiconductor chip having a second hydrophilic top surface, wherein a second periphery of the second hydrophilic top surface has a second shape, and wherein the second shape is a mirror image of the first shape; applying a polar liquid to the first hydrophilic top surface, wherein an extent of the polar liquid is bounded by the first shape; and placing the second semiconductor chip on the polar liquid, wherein the polar liquid wets the second hydrophilic top surface, wherein the first periphery is self-aligned to the second periphery.

According to another aspect of the present invention, another method of forming a semiconductor structure is provided. This method includes providing a first semiconductor chip including a first hydrophilic top surface and a first hydrophobic top surface, wherein the first hydrophilic top surface has a first periphery having a first shape, and wherein the first hydrophobic top surface laterally abuts and laterally surrounds the first periphery; providing a second semiconductor chip having a second hydrophilic top surface, wherein a second periphery of the second hydrophilic top surface has a second shape, and wherein the second shape is a mirror image of the first shape; applying a polar liquid to the first hydrophilic top surface, wherein an extent of the polar liquid is bounded by the first shape; and placing the second semiconductor chip on the polar liquid, wherein the polar liquid wets the second hydrophilic top surface, and wherein the first periphery is self-aligned to the second periphery.

### BRIEF DESCRIPTION OF THE DRAWINGS

FIGS. 1A-1C are sequential vertical cross-sectional views of a first exemplary semiconductor structure according to a first embodiment of the present invention.

FIGS. 2A-2C are sequential vertical cross-sectional views of a second exemplary semiconductor structure according to a second embodiment of the present invention.

FIGS. 3A-3C are sequential vertical cross-sectional views of a third exemplary semiconductor structure according to a third embodiment of the present invention.

FIGS. 4A-4C are sequential vertical cross-sectional views of a fourth exemplary semiconductor structure according to a fourth embodiment of the present invention.

FIG. 5A is a top-down view of a top surface of a second semiconductor chip according to the first embodiment and the third embodiment.

FIG. 5B is a top-down view of a top surface of a first semiconductor chip according to the first embodiment and the second embodiment.

FIG. 6A is a top-down view of a top surface of a second semiconductor chip according to the second embodiment and the fourth embodiment.

FIG. 6B is a top-down view of a top surface of a first semiconductor chip according to the third embodiment and the fourth embodiment.

FIGS. 7A and 7B are sequential vertical cross-sectional views of a fifth exemplary semiconductor structure according to a fifth embodiment of the present invention.

FIGS. 8A and 8B are sequential vertical cross-sectional views of a sixth exemplary semiconductor structure according to a sixth embodiment of the present invention.

FIGS. 9A and 9B are sequential vertical cross-sectional views of a seventh exemplary semiconductor structure according to a seventh embodiment of the present invention.

FIGS. 10A and 10B are sequential vertical cross-sectional views of an eighth exemplary semiconductor structure according to an eighth embodiment of the present invention.

FIGS. 11A and 11B are sequential vertical cross-sectional views of a ninth exemplary semiconductor structure according to a ninth embodiment of the present invention.

FIGS. 12A and 12B are sequential vertical cross-sectional views of a tenth exemplary semiconductor structure according to a tenth embodiment of the present invention.

### DETAILED DESCRIPTION OF THE INVENTION

As stated above, the present invention relates to methods of stacking semiconductor chips in self-alignment, which are now described in detail with accompanying figures. Throughout the drawings, the same reference numerals or letters are used to designate like or equivalent elements. The drawings are not necessarily drawn to scale.

As used herein, a “semiconductor chip” is a structure including at least one of an integrated circuit, a passive component such as a capacitor, a resistor, an inductor, or a diode, or a micro-mechanical-electrical structure (MEMS), or a combination thereof that may be formed on a semiconductor substrate, an insulating substrate, or a conductive substrate.

As used herein, a “hydrophilic” surface is a surface having a property of being wetted by water. In general, a hydrophilic surface is wetted not only by water, but also by any polar liquid. An exemplary hydrophilic surface is the surface of silicon oxide.

As used herein, a “polar liquid” is a liquid having a non-zero electric dipole moment. Molecules of a polar liquid are aligned in the presence of an external electric field. For example, the electric field generated by a hydrophilic surface aligns molecules of a polar liquid. Polar liquids wet a hydrophilic surface.

As used herein, a “hydrophobic” surface is a surface having a property of not being wetted by water. In general, a hydrophobic surface is not wetted by water or by a polar liquid. An exemplary hydrophobic material is silicon.

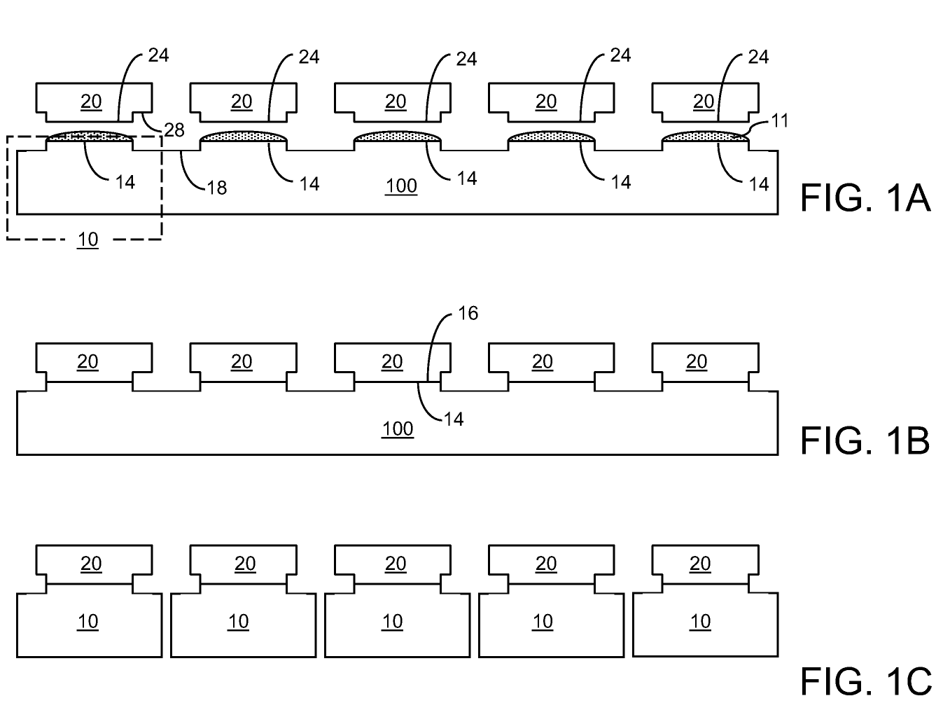

Referring to FIG. 1A, a first exemplary semiconductor structure according to a first embodiment of the present invention comprises a substrate 100 embedding a plurality of first chips 10. The first exemplary structure further includes a plurality of second chips 20, which are shown upside down. Each first chip 10 includes at least one first device, and each second chip 20 includes at least one second device. The substrate and chips discussed supra could be formed from a semiconductor, such as silicon, or from an insulator, such as silica glass. The devices on the chips could be passive elements, such as micromechanical (MEMS) switches, passive elements, such as metal-insulator-metal (MIM) capacitors, integrated circuits (IC's) formed from semiconductors transistors, etc. If the chips are IC's, then the number of semiconductor devices in each of the first and second semiconductor chips (10, 20) is typically over one million. Although we will refer to substrate 100 as a semiconductor substrate and first and second chips 10 and 20 as integrated circuits for the remainder of the detailed description of the invention, it should be remembered that non-IC's are also envisioned. The semiconductor substrate 100 may be a bulk substrate, a semiconductor-on-insulator (SOI) substrate, or a hybrid substrate including bulk portions and SOI portions. The semiconductor substrate 100 is of integral and unitary construction, i.e., in one contiguous piece. Thus, the first semiconductor chips 10 are not diced into individual semiconductor chips at this point. In contrast, the second semiconductor chips 20 are diced into individual semiconductor chips.

While the present invention is described employing second semiconductor chips 20 that are individually diced, embodiments of the present invention are explicitly contemplated in which the second semiconductor chips 20 are embedded in another semiconductor substrate (not shown) so that chip stacking is performed between two semiconductor substrates.

The first semiconductor chips 10 may have an identical design, or different designs. Likewise, the second semiconductor chips 20 may have another identical design, or different designs. Typically, each of the first semiconductor chips 10 has an identical design, and each of the second semiconductor chips 20 has the another identical design, which may be the same as the design of the first semiconductor chips 10 or different from the design of the first semiconductor chips 20.

Each of the first and second semiconductor chips (10, 20) includes a semiconductor material portion including a semiconductor material. The semiconductor material may be selected from, but is not limited to, silicon, germanium, silicon-germanium alloy, silicon carbon alloy, silicon-germanium-carbon alloy, gallium arsenide, indium arsenide, indium phosphide, III V compound semiconductor materials, II-VI compound semiconductor materials, organic semiconductor materials, and other compound semiconductor materials. For example, the semiconductor material may comprise single crystalline silicon. Semiconductor devices are formed on semiconductor material portions in the first and second semiconductor chips (10, 20). The first and second semiconductor chips (10, 20) may include metal interconnect structures that interconnect the semiconductor devices within each first or second semiconductor chip (10, 20).

Each first semiconductor chip 10 includes a mesa that has a first hydrophilic top surface 14. The periphery of the mesa, which is herein referred to as a first periphery, has a first shape. The first shape may be a polygon, a curvilinear shape, or a combination thereof. The first shape may be a rectangle. The size of the first hydrophilic top surface 14 may be on the order of the total area of a first semiconductor chip 10, but is less than the total area of the first semiconductor chip 10. The rest of the area of the first semiconductor chip 10, which is a peripheral region surrounding the mesa, is recessed relative to the first hydrophilic top surface 14. The peripheral region adjoins a substantially vertical sidewall surface at the first periphery, and is herein referred to as a first recessed peripheral region 18. The first hydrophilic top surface 14 and the first recessed peripheral region 18 are vertically offset by an offset distance, which may be from 50 nm to 20 microns, and is typically from 200 nm to 5 microns. The lateral dimensions, e.g., length and width, of each of the first and second semiconductor chips (10, 20) may be from 0.5 mm to 50 mm, and typically from 3 mm to 25 mm, although lesser and greater lateral dimensions are also contemplated herein.

Each second semiconductor chip 20 includes another mesa that has a second hydrophilic top surface 24. The periphery of the mesa, which is herein referred to as a second periphery, has a second shape. The second shape may be a polygon, a curvilinear shape, or a combination thereof. The second shape may be a rectangle. Preferably, the second shape is a mirror image of the first shape. The size of the second hydrophilic top surface 24 may be on the order of the total area of a second semiconductor chip 20, but is less than the total area of the second semiconductor chip 20. The rest of the area of the second semiconductor chip 20, which is a peripheral region surrounding the mesa, is recessed relative to the second hydrophilic top surface 24. The peripheral region adjoins a substantially vertical sidewall surface at the second periphery, and is herein referred to as a second recessed peripheral region 28. The second hydrophilic top surface 24 and the second recessed peripheral region 28 are vertically offset by another offset distance, which may be from 50 nm to 20 microns, and is typically from 200 nm to 5 microns.

A polar liquid 11 is applied to the first hydrophilic top surface 14. The polar liquid 11 may be any liquid that wets a hydrophilic surface. Molecules of the polar liquid 11 have a non-zero electric dipole moment. The polar liquid 11 may comprise one type of molecules having a non-zero electric dipole moment, or may comprise a plurality of types of molecules among which at least one type of molecule has a non-zero electric dipole moment. For example, the polar liquid 11 may be selected from a pH-neutral water, an acidic solution, a base solution, a hydrogen-peroxide-containing water solution, acetone, methanol, and hydrocarbon based polar liquids.

Each droplet of the polar liquid 11 wets a first hydrophilic top surface 14. In one embodiment, a plurality of first hydrophilic top surfaces 14 may be wetted by the polar liquid 11 simultaneously. In another embodiment, the first hydrophilic top surfaces 14 may be wetted by droplets of the polar liquid 11 sequentially. The extent of the polar liquid 11 on each first hydrophilic top surface 14 is bounded by the first shape so that the edges of the polar liquid 11 coincide with the first periphery by surface tension.

A second semiconductor chip 20 is placed on each first semiconductor chip 10 having the polar liquid 11 on the first hydrophilic top surface 14. The polar liquid 11 wets the second hydrophilic top surface 24 of each second semiconductor chip 20. Each second semiconductor chip 20 is placed over the first semiconductor chip 10 so that the second periphery of the second semiconductor chip 20 roughly overlaps with the first periphery of the first semiconductor chip 10. The overlay between the first periphery and the second periphery depends on the accuracy of the process employed to place the second semiconductor chips 20 on the first semiconductor chips 10. The overlay tolerance of the placement process may be from 0.5 micron to 20 microns, and typically from 1 micron to 10 microns, although lesser and greater overlay tolerances are also contemplated herein.

Each pair of a first semiconductor chip 10 and a second semiconductor chip 20 wetted by the same droplet of the polar liquid 11 is self-aligned as the second semiconductor chip 20. The second semiconductor chip 20 is free to move laterally over the polar liquid. To minimize the surface tension, the second semiconductor chip 20 is moved by the polar liquid 11 so as to achieve a minimum surface area for the portion of droplet of the polar liquid that does not wet a first hydrophilic top surface 14 or a second hydrophilic top surface 24.

In other words, the surface tension of the polar liquid 11 induces lateral movement of the second semiconductor chip 20 relative to the first semiconductor chip 10 wetted by the same droplet of the polar liquid 11. Thus, each second semiconductor chip 20 is self-aligned to the first semiconductor chip 10 that is located directly underneath. In case the second periphery is a mirror image of the first periphery, the second periphery vertically overlaps the first periphery.

Referring to FIG. 1B, the first semiconductor chips 10 and the second semiconductor chips 20 form bonded structures. The bonding of each pair of a first semiconductor chip 10 and a second semiconductor chip 20 may be effected by allowing the polar liquid to dry out by evaporation, either at room temperature or during a low temperature anneal. If a low temperature anneal is used, temperatures ranging from 50° C. to 150° C. are envisioned, but higher temperatures, up to the maximum temperature allowed by the materials on the chip (i.e. 400 C) could be used. Optionally, pressure may be applied to the backside (non-bonded side) of the second semiconductor chips 20 so that the polar liquid 11 is squeezed out of the interface between an adjoined pair of a first semiconductor chip 10 and a second semiconductor chip 20. The bonding of pairs of a first semiconductor chip 10 and a second semiconductor chip 20 may be affected simultaneously or sequentially. Once the polar liquid 11 is removed from the interface between each pair of a first semiconductor chip 10 and a second semiconductor chip 20, the bonding of the pair of the first and second semiconductor chips (10, 20) is complete.

Referring to FIG. 1C, each bonded pair of a first semiconductor chip 10 and a second semiconductor chip 20 is separated from one another by dicing. Specifically, the semiconductor substrate 100 is diced along dicing channels provided between each adjacent die including one of the first semiconductor chips 10. A plurality of stacked and bonded semiconductor chips is obtained by the dicing of the semiconductor substrate 100. Each of the stacked and bonded semiconductor chips includes a first semiconductor chip 10 and a second semiconductor chip 20.

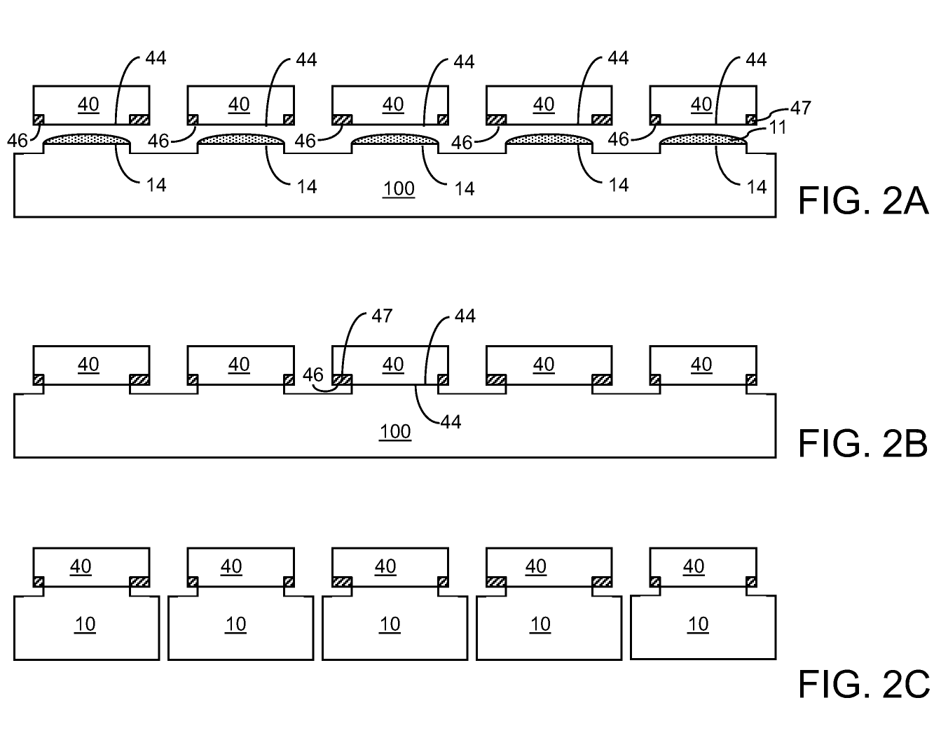

Referring to FIG. 2A, a second exemplary semiconductor structure according to a second embodiment of the present invention employs the same semiconductor substrate 100 including first semiconductor chips 10 as in the first embodiment. A plurality of second semiconductor chips 40 are employed in the second embodiment.

Each second semiconductor chip 40 includes a second hydrophilic top surface 44 and a hydrophobic surface, which is herein referred to as a second hydrophobic top surface 46. Specifically, each second semiconductor chip 40 includes a hydrophobic material portion, which is herein referred to as a second hydrophobic material portion 47. The surface of each second hydrophobic material portion 47 is a second hydrophobic top surface 46. Each second hydrophilic top surface 44 has a periphery, which is herein referred to as a second periphery. Each second hydrophobic top surface 46 laterally abuts and laterally surrounds a second periphery. In some cases, the second hydrophobic top surface 46 and the second hydrophilic top surface 44 surrounded thereby may be substantially coplanar.

Each second periphery has a second shape. The second shape may be a polygon, a curvilinear shape, or a combination thereof. The second shape may be a rectangle. Preferably, the second shape is a mirror image of the first shape. The size of the second hydrophilic top surface 44 may be on the order of the total area of a second semiconductor chip 40, but is less than the total area of the second semiconductor chip 40. The rest of the area of the second semiconductor chip 40 is occupied by a second hydrophobic top surface 46. The second hydrophobic top surface 46 adjoins the entirety of the second periphery of the second semiconductor chip 40.

A polar liquid 11 is applied to the first hydrophilic top surface 14 as in the first embodiment. The polar liquid 11 may comprise the same material as in the first embodiment. Each droplet of the polar liquid 11 wets a first hydrophilic top surface 14. The extent of the polar liquid 11 on each first hydrophilic top surface 14 is bounded by the first shape so that the edges of the polar liquid 11 coincide with the first periphery by surface tension.

A second semiconductor chip 40 is placed on each first semiconductor chip 10 having the polar liquid 11 on the first hydrophilic top surface 14. The polar liquid 11 wets the second hydrophilic top surface 44 of each second semiconductor chip 40. Each second semiconductor chip 40 is placed over the first semiconductor chip 10 so that the second periphery of the second semiconductor chip 40 roughly overlaps with the first periphery of the first semiconductor chip 10. The overlay between the first periphery and the second periphery depends on the accuracy of the process employed to place the second semiconductor chips 40 on the first semiconductor chips 10 as in the first embodiment.

Each second hydrophobic top surface 46 is hydrophobic, i.e., is not wetted by a polar liquid. Thus, when the polar liquid touches the second hydrophilic top surface 44, the extent of the wetting of the second semiconductor chip 40 coincides with the second periphery. The second semiconductor chip 40 is free to move laterally over the polar liquid. To minimize the surface tension, the second semiconductor chip 40 is moved by the polar liquid 11 so as to achieve a minimum surface area for the portion of droplet of the polar liquid that does not wet a first hydrophilic top surface 14 or a second hydrophilic top surface 44.

Each pair of a first semiconductor chip 10 and a second semiconductor chip 40 wetted by the same droplet of the polar liquid 11 is self-aligned as the second semiconductor chip 40. The surface tension of the polar liquid 11 induces lateral movement of the second semiconductor chip 40 relative to the first semiconductor chip 10 wetted by the same droplet of the polar liquid 11. Thus, each second semiconductor chip 40 is self-aligned to the first semiconductor chip 10 that is located directly underneath. In case the second periphery is a mirror image of the first periphery, the second periphery vertically overlaps the first periphery.

Referring to FIG. 2B, the first semiconductor chips 10 and the second semiconductor chips 40 form bonded structures in the same manner as in the first embodiment. Once the polar liquid 11 is removed from the interface between each pair of a first semiconductor chip 10 and a second semiconductor chip 40, the bonding of the pair of the first and second semiconductor chips (10, 40) is complete.

Referring to FIG. 2C, each bonded pair of a first semiconductor chip 10 and a second semiconductor chip 40 is separated from one another by dicing in the same manner as in the first embodiment. Each of the stacked and bonded semiconductor chips includes a first semiconductor chip 10 and a second semiconductor chip 40.

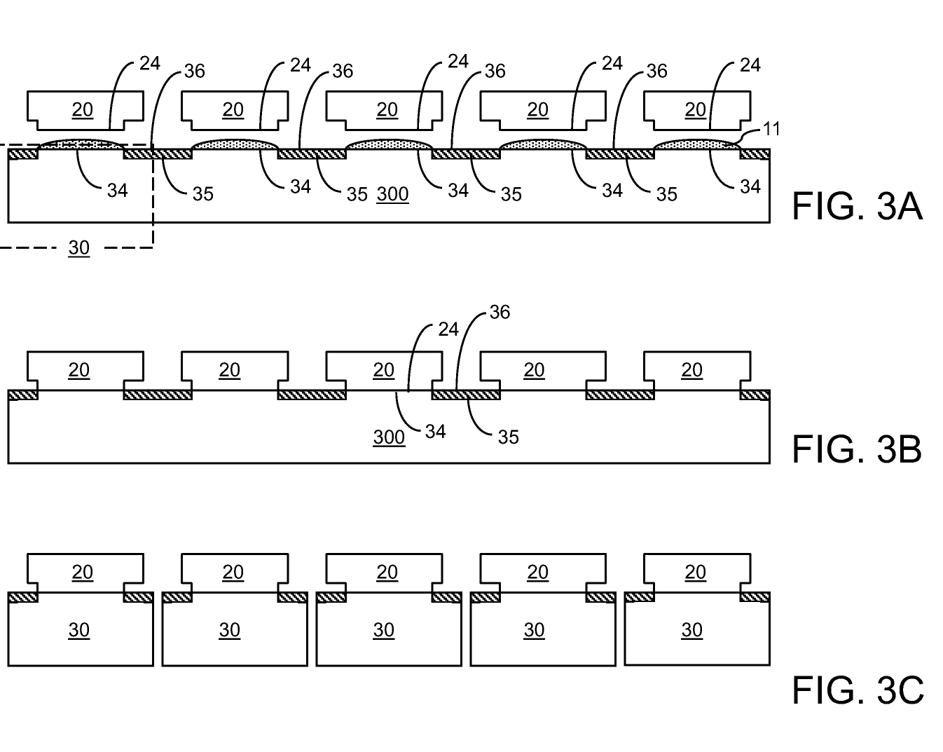

Referring to FIG. 3A, a third exemplary semiconductor structure according to a third embodiment of the present invention comprises a semiconductor substrate 300 embedding a plurality of first semiconductor chips 30. The third exemplary semiconductor structure further includes a plurality of second semiconductor chips 20, which are shown upside down. The second semiconductor chips 20 may be the same as in the first embodiment. Each first semiconductor chip 30 includes at least one first semiconductor device, and each second semiconductor chip 20 includes at least one second semiconductor device. The number of semiconductor devices in each of the first and second semiconductor chips (30, 20) is typically over one million. The semiconductor substrate 300 may be a bulk substrate, a semiconductor-on-insulator (SOI) substrate, or a hybrid substrate including bulk portions and SOI portions. The semiconductor substrate 300 is of integral and unitary construction, i.e., in one contiguous piece. Thus, the first semiconductor chips 30 are not diced into individual semiconductor chips at this point. In contrast, the second semiconductor chips 20 are diced into individual semiconductor chips.

The first semiconductor chips 30 may have an identical design, or different designs. Likewise, the second semiconductor chips 20 may have another identical design, or different designs. Typically, each of the first semiconductor chips 30 has an identical design, and each of the second semiconductor chips 20 has the another identical design, which may be the same as the design of the first semiconductor chips 30 or different from the design of the first semiconductor chips 20. Each of the first and second semiconductor chips (30, 20) includes a semiconductor material portion including a semiconductor material, which may be the same as in the first embodiment.

Each first semiconductor chip 30 includes a first hydrophilic top surface 34 and a hydrophobic surface, which is herein referred to as a first hydrophobic top surface 36. Specifically, each first semiconductor chip 30 includes a hydrophobic material portion, which is herein referred to as a first hydrophobic material portion 35. The surface of each first hydrophobic material portion 35 is a first hydrophobic top surface 36. Each first hydrophilic top surface 34 has a periphery, which is herein referred to as a first periphery. Each first hydrophobic top surface 36 laterally abuts and laterally surrounds a first periphery. In some cases, the first hydrophobic top surface 36 and the first hydrophilic top surface 34 surrounded thereby may be substantially coplanar.

Each first periphery has a first shape. The first shape may be a polygon, a curvilinear shape, or a combination thereof. The first shape may be a rectangle. The size of the first hydrophilic top surface 34 may be on the order of the total area of a first semiconductor chip 30, but is less than the total area of the first semiconductor chip 30. The rest of the area of the first semiconductor chip 30 is occupied by a first hydrophobic top surface 36. The first hydrophobic top surface 36 adjoins the entirety of the first periphery of the first semiconductor chip 30.

Each second semiconductor chip 20 includes a mesa that has a second hydrophilic top surface 24 as in the first embodiment. The periphery of the mesa, which is herein referred to as a second periphery, has a second shape. The second shape may be a polygon, a curvilinear shape, or a combination thereof. The second shape may be a rectangle. Preferably, the second shape is a mirror image of the first shape. Other features of the second semiconductor chips 20 may be the same as in the first embodiment.

A polar liquid 11 is applied to the first hydrophilic top surface 34. The polar liquid 11 may be any liquid that wets a hydrophilic surface, and may be the same as in the first embodiment. Each droplet of the polar liquid 11 wets a first hydrophilic top surface 34. The extent of each droplet of the polar liquid is bounded by the first shape of each first semiconductor chip 30 to which the polar liquid 11 is applied. Specifically, the hydrophilic property of each of the first hydrophilic top surfaces 34 induces a complete coverage of each first hydrophilic top surface 34 by the polar liquid 11. At the same time, the hydrophobic property of each of the first hydrophobic top surfaces 36 prevents coverage of the first hydrophobic top surfaces 36 by the polar liquid 11. Thus, the extent of the polar liquid 11 is bounded by the first shape, i.e., the boundary of the polar liquid 11 coincides with the first periphery of each of the first semiconductor chips 30. In other words, the edges of the polar liquid 11 coincide with the first periphery by surface tension.

A second semiconductor chip 20 is placed on each first semiconductor chip 30 having the polar liquid 11 on the first hydrophilic top surface 34. The polar liquid 11 wets the second hydrophilic top surface 24 of each second semiconductor chip 20. Each second semiconductor chip 20 is placed over the first semiconductor chip 30 so that the second periphery of the second semiconductor chip 20 roughly overlaps with the first periphery of the first semiconductor chip 30. As in the first embodiment, the overlay between the first periphery and the second periphery depends on the accuracy of the process employed to place the second semiconductor chips 20 on the first semiconductor chips 30.

Each pair of a first semiconductor chip 30 and a second semiconductor chip 20 wetted by the same droplet of the polar liquid 11 is self-aligned as the second semiconductor chip 20. The second semiconductor chip 20 is free to move laterally over the polar liquid. To minimize the surface tension, the second semiconductor chip 20 is moved by the polar liquid 11 so as to achieve a minimum surface area for the portion of droplet of the polar liquid that does not wet a first hydrophilic top surface 34 or a second hydrophilic top surface 24. Each second semiconductor chip 20 is self-aligned to the first semiconductor chip 30 that is located directly underneath as the second hydrophilic top surface 24 is self-aligned to the first hydrophilic top surface 34 located directly underneath. In case the second periphery is a mirror image of the first periphery, the second periphery vertically overlaps the first periphery.

Referring to FIG. 3B, the first semiconductor chips 30 and the second semiconductor chips 20 form bonded structures in the same manner as in the first and second embodiments. Once the polar liquid 11 is removed from the interface between each pair of a first semiconductor chip 30 and a second semiconductor chip 20, the bonding of the pair of the first and second semiconductor chips (30, 20) is complete.

Referring to FIG. 3C, each bonded pair of a first semiconductor chip 30 and a second semiconductor chip 20 is separated from one another by dicing in the same manner as in the first and second embodiments. Each of the stacked and bonded semiconductor chips includes a first semiconductor chip 30 and a second semiconductor chip 20.

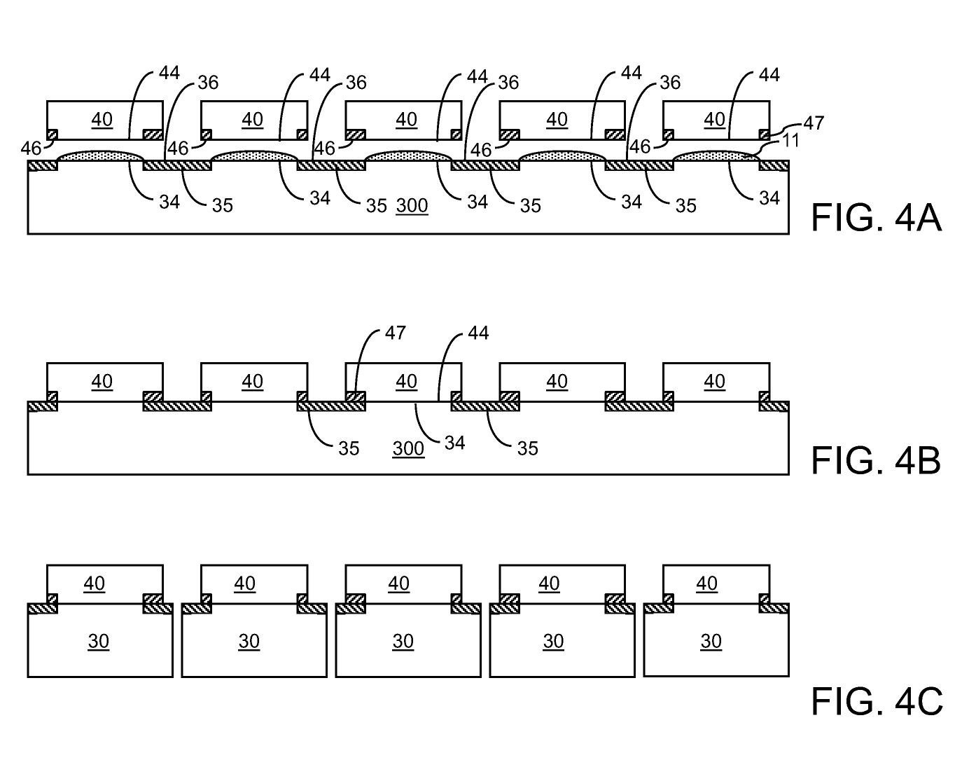

Referring to FIG. 4A, a fourth exemplary semiconductor structure according to a fourth embodiment of the present invention employs the same semiconductor substrate 300 including first semiconductor chips 30 as in the third embodiment. Each first semiconductor chip 30 may be the same as in the third embodiment. Further, the fourth exemplary semiconductor structure employs a plurality of second semiconductor chips 40 which may be the same as in the second embodiment. As in the first through third embodiments, the second shape is a mirror image of the first shape.

A polar liquid 11 is applied to the first hydrophilic top surface 34. The polar liquid 11 may be any liquid that wets a hydrophilic surface, and may be the same as in the first embodiment. Each droplet of the polar liquid 11 wets a first hydrophilic top surface 34. The extent of each droplet of the polar liquid is bounded by the first shape of each first semiconductor chip 30 to which the polar liquid 11 is applied. Specifically, the hydrophilic property of each of the first hydrophilic top surfaces 34 induces a complete coverage of each first hydrophilic top surface 34 by the polar liquid 11. At the same time, the hydrophobic property of each of the first hydrophobic top surfaces 36 prevents coverage of the first hydrophobic top surfaces 36 by the polar liquid 11. Thus, the extent of the polar liquid 11 is bounded by the first shape, i.e., the boundary of the polar liquid 11 coincides with the first periphery of each of the first semiconductor chips 30. In other words, the edges of the polar liquid 11 coincide with the first periphery by surface tension.

A second semiconductor chip 40 is placed on each first semiconductor chip 30 having the polar liquid 11 on the first hydrophilic top surface 34. The polar liquid 11 wets the second hydrophilic top surface 44 of each second semiconductor chip 40. Each second semiconductor chip 40 is placed over the first semiconductor chip 30 so that the second periphery of the second semiconductor chip 40 roughly overlaps with the first periphery of the first semiconductor chip 30. As in the first embodiment, the overlay between the first periphery and the second periphery depends on the accuracy of the process employed to place the second semiconductor chips 40 on the first semiconductor chips 30.

Each droplet of the polar liquid 11 wets a second hydrophilic top surface 44. Each pair of a first semiconductor chip 30 and a second semiconductor chip 40 wetted by the same droplet of the polar liquid 11 is self-aligned as the second semiconductor chip 40. The second semiconductor chip 40 is free to move laterally over the polar liquid. To minimize the surface tension, the second semiconductor chip 40 is moved by the polar liquid 11 so as to achieve a minimum surface area for the portion of droplet of the polar liquid that does not wet a first hydrophilic top surface 34 or a second hydrophilic top surface 44. In this case, the extent of each droplet of the polar liquid is bounded by the second shape of each second semiconductor chip 40 that the polar liquid 11 wets. Specifically, the hydrophilic property of each of the second hydrophilic top surfaces 44 induces a complete coverage of each second hydrophilic top surface 44 by the polar liquid 11. At the same time, the hydrophobic property of each of the second hydrophobic top surfaces 46 prevents coverage of the second hydrophobic top surfaces 46 by the polar liquid 11. Thus, the extent of the polar liquid 11 is bounded by the second shape, i.e., the boundary of the polar liquid 11 coincides with the second periphery of each of the second semiconductor chips 40. In other words, the edges of the polar liquid 11 coincide with the second periphery by surface tension.

Thus, each second semiconductor chip 40 is self-aligned to the first semiconductor chip 30 that is located directly underneath as the second hydrophilic top surface 44 is self-aligned to the first hydrophilic top surface 34 located directly underneath. In case the second periphery is a mirror image of the first periphery, the second periphery vertically overlaps the first periphery.

Referring to FIG. 4B, the first semiconductor chips 30 and the second semiconductor chips 40 form bonded structures in the same manner as in the first through third embodiments. Once the polar liquid 11 is removed from the interface between each pair of a first semiconductor chip 30 and a second semiconductor chip 40, the bonding of the pair of the first and second semiconductor chips (30, 40) is complete.

Referring to FIG. 4C, each bonded pair of a first semiconductor chip 30 and a second semiconductor chip 40 is separated from one another by dicing in the same manner as in the first through third embodiments. Each of the stacked and bonded semiconductor chips includes a first semiconductor chip 30 and a second semiconductor chip 40.

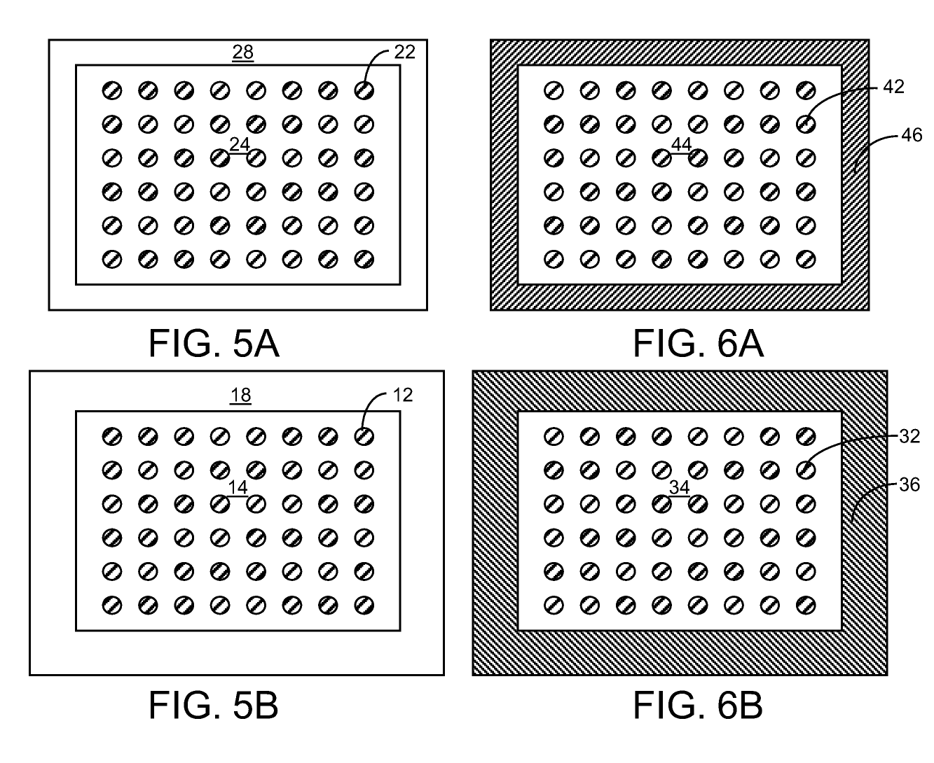

Referring to FIG. 5A, top surfaces of a second semiconductor chip 20 is shown according to the first embodiment and the third embodiment. The top surfaces of the second semiconductor chip 20 include a second hydrophilic top surface 24 and a second hydrophobic top surface 28. As described above, the second hydrophobic top surface 28 is recessed relative to the second hydrophilic top surface 24. The second hydrophilic top surface 24 typically includes a second array of top surfaces of second conductive contact structures 22. The second conductive contact structures 22 typically comprise metals, nitridized metals, or alloys such as Cu, Au, Ag, Al, Sn, In, Pb, Ta, TaN, TiN, and W. Preferably, the entirety of the second hydrophilic top surface 24 is planar.

Referring to FIG. 5B, top surfaces of a first semiconductor chip 10 is shown according to the first embodiment and the second embodiment. The top surfaces of the first semiconductor chip 10 include a first hydrophilic top surface 14 and a first hydrophobic top surface 18. As described above, the first hydrophobic top surface 18 is recessed relative to the first hydrophilic top surface 14. The first hydrophilic top surface 14 typically includes a first array of top surfaces of first conductive contact structures 12. The first conductive contact structures 12 typically comprise metal such as Cu, Au, Ag, Al, and W. Preferably, the entirety of the first hydrophilic top surface 14 is planar.

Referring to FIG. 6A, top surfaces of a second semiconductor chip 40 is shown according to the second embodiment and the fourth embodiment. The top surfaces of the second semiconductor chip 40 include a second hydrophilic top surface 44 and a second hydrophobic top surface 46. The entirety of the second hydrophilic top surface 44 is planar. Preferably, the second hydrophobic top surface 46 is substantially coplanar with the second hydrophilic top surface 44. The second hydrophilic top surface 44 typically includes a second array of top surfaces of second conductive contact structures 42. The second conductive contact structures 42 typically comprise metal such as Cu, Au, Ag, Al, and W.

Referring to FIG. 6B, top surfaces of a first semiconductor chip 30 is shown according to the third embodiment and the fourth embodiment. The top surfaces of the first semiconductor chip 30 include a first hydrophilic top surface 34 and a first hydrophobic top surface 36. The entirety of the first hydrophilic top surface 34 is planar. Preferably, the first hydrophobic top surface 36 is substantially coplanar with the first hydrophilic top surface 34. The first hydrophilic top surface 34 typically includes a first array of top surfaces of first conductive contact structures 32. The first conductive contact structures 32 typically comprise metal such as Cu, Au, Ag, Al, and W.

Across FIGS. 5A, 5B, 6A and 6B, a second array is preferably a mirror image of a first array between a pair of a first semiconductor chip (10 or 30) and a second semiconductor chip (20 or 40) that are bonded so that each first conductive contact structures (12 or 32) in a first array directly contacts a second conductive contact structure (22 or 42) in a second array. In case the first periphery is a mirror image of the second periphery and a first array of first conductive contact structures (12 or 32) is a mirror image of a second array of second conductive contact structures (22 or 42), the first array of first conductive contact structures (12 or 32) is self-aligned to the second array of second conductive contact structures (22 or 42). In this case, the self-alignment between a first semiconductor chip (10 or 30) and a second semiconductor chip (20 or 40) has less overlay variation than the overlay variation of a tool employed to align the two semiconductor chips during placement of the second semiconductor chip (20 or 40) over the first semiconductor chip (10 or 30) having a first hydrophilic top surface (14 or 34) covered with the polar liquid 11.

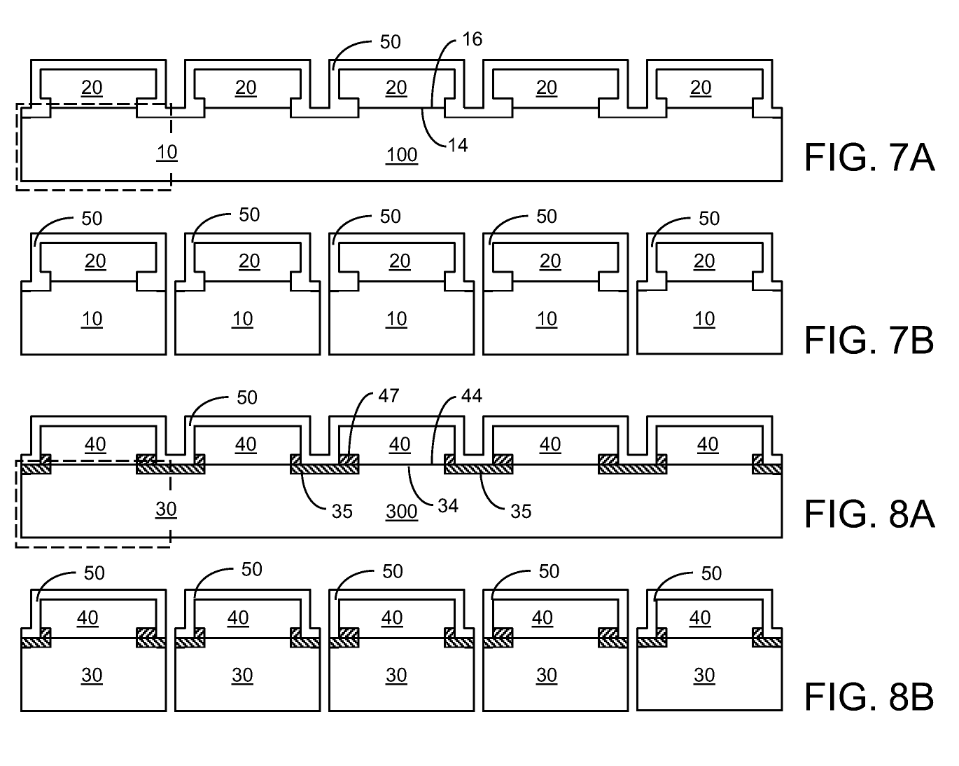

Referring to FIG. 7A, a fifth exemplary semiconductor structure according to a fifth embodiment of the present invention is derived from the first exemplary semiconductor structure of FIG. 1B by depositing a material layer 50. The material layer 50 is deposited around the interface between the first semiconductor chips 10 and the second semiconductor chips 20. The material layer 50 provides a hermetic seal between each vertically stacked pair of a first semiconductor chip 10 and a second semiconductor chip 20.

The material layer 50 comprises a material that may block diffusion of impurities or moisture. For example, the material layer 50 may comprise a polymer such as polyimide, silicon nitride, a silicon oxide/silicon nitride stack, a silicon oxide/silicon nitride/polyimide stack, an elemental metal such as Cu, an intermetallic alloy, a lead-containing solder material, or a lead-free solder material. A reflow process may be performed to improve the hermetic seal provided by the material layer 50.

Referring to FIG. 7B, each bonded pair of a first semiconductor chip 10 and a second semiconductor chip 20 is separated from one another by dicing in the same manner as in the first embodiment. Each of the stacked and bonded semiconductor chips includes a first semiconductor chip 10 and a second semiconductor chip 20.

Referring to FIG. 8A, a sixth exemplary semiconductor structure according to a sixth embodiment of the present invention is derived from the fourth exemplary semiconductor structure of FIG. 4B by depositing a material layer 50. The material layer 50 is deposited around the interface between the first semiconductor chips 30 and the second semiconductor chips 40. The material layer 50 provides a hermetic seal between each vertically stacked pair of a first semiconductor chip 30 and a second semiconductor chip 40 in the same manner as in the fifth embodiment. The material layer 50 may comprise the same material as in the fifth embodiment. A reflow process may be performed to improve the hermetic seal provided by the material layer 50.

Referring to FIG. 8B, each bonded pair of a first semiconductor chip 30 and a second semiconductor chip 40 is separated from one another by dicing in the same manner as in the fourth embodiment. Each of the stacked and bonded semiconductor chips includes a first semiconductor chip 30 and a second semiconductor chip 40.

Embodiments modifying the second exemplary semiconductor structure of FIG. 2B and the third exemplary semiconductor structure of FIG. 3B in the same manner as in the fifth and sixth embodiments are explicitly contemplated herein.

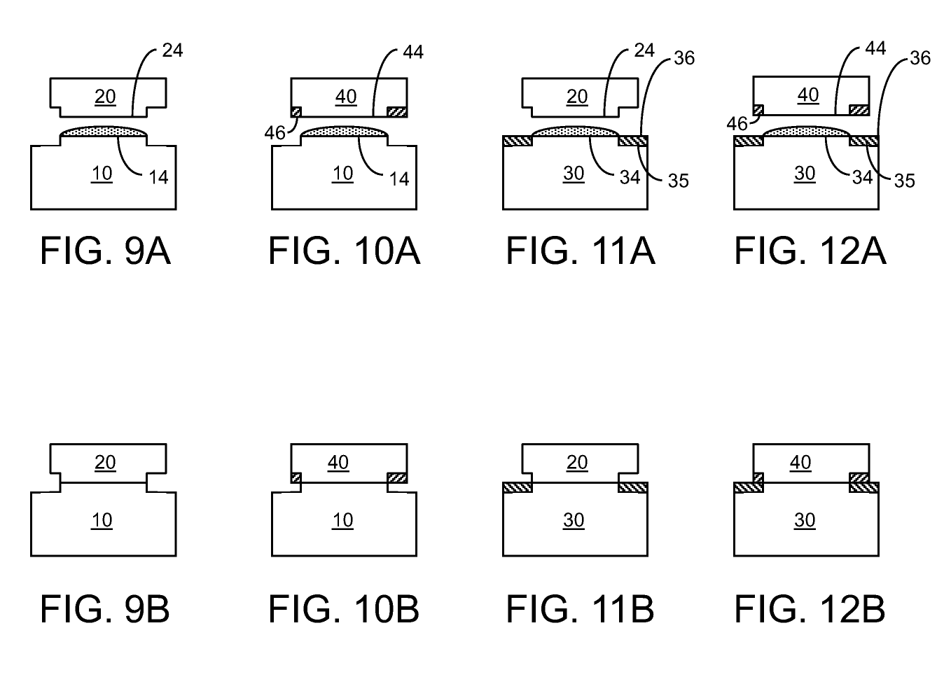

Referring to FIG. 9A, a seventh exemplary semiconductor structure according to a seventh embodiment of the present invention is shown. According to the seventh embodiment, a first semiconductor chip 10 is provided, for example, by dicing a semiconductor substrate (not shown) including a plurality of semiconductor chips. Thus, a first semiconductor chip 10 in the seventh embodiment is provided as a single semiconductor chip that is not adjoined to another semiconductor chip prior to application of a polar liquid 11.

The first semiconductor chip 10 of the seventh embodiment has the same features as a first semiconductor chip 10 of the first embodiment except that the first semiconductor chip 10 of the seventh embodiment is an isolated single semiconductor chip. The second semiconductor chip 20 of the seventh embodiment is the same as the second semiconductor chip 20 of the first embodiment. The same processing steps are employed as in the first embodiment to apply the polar liquid 11. The polar liquid 11 may be the same as in the first embodiment.

Referring to FIG. 9B, the first semiconductor chip 10 and the second semiconductor chip 20 form a bonded structure in the same manner as in the first embodiment. Once the polar liquid 11 is removed from the interface between the pair of the first semiconductor chip 10 and the second semiconductor chip 20, the bonding of the pair of the first and second semiconductor chips (10, 20) is complete.

Referring to FIG. 10A, an eighth exemplary semiconductor structure according to an eighth embodiment of the present invention is shown. According to the eighth embodiment, a first semiconductor chip 10 is provided as a single semiconductor chip in the same manner as in the seventh embodiment.

The first semiconductor chip 10 of the eighth embodiment has the same features as a first semiconductor chip 10 of the first and second embodiments except that the first semiconductor chip 10 of the eighth embodiment is an isolated single semiconductor chip. The second semiconductor chip 40 of the eighth embodiment is the same as the second semiconductor chip 40 of the second embodiment. The same processing steps are employed as in the second embodiment to apply the polar liquid 11. The polar liquid 11 may be the same as in the first embodiment.

Referring to FIG. 10B, the first semiconductor chip 10 and the second semiconductor chip 40 form a bonded structure in the same manner as in the second embodiment. Once the polar liquid 11 is removed from the interface between the pair of the first semiconductor chip 10 and the second semiconductor chip 40, the bonding of the pair of the first and second semiconductor chips (10, 40) is complete.

Referring to FIG. 11A, a ninth exemplary semiconductor structure according to a ninth embodiment of the present invention is shown. According to the ninth embodiment, a first semiconductor chip 30 is provided, for example, by dicing a semiconductor substrate (not shown) including a plurality of semiconductor chips. Thus, a first semiconductor chip 30 in the ninth embodiment is provided as a single semiconductor chip that is not adjoined to another semiconductor chip prior to application of a polar liquid 11.

The first semiconductor chip 30 of the ninth embodiment has the same features as a first semiconductor chip 30 of the third embodiment except that the first semiconductor chip 30 of the ninth embodiment is an isolated single semiconductor chip. The second semiconductor chip 20 of the ninth embodiment is the same as the second semiconductor chip 20 of the first and third embodiments. The same processing steps are employed as in the third embodiment to apply the polar liquid 11. The polar liquid may be the same as in the first embodiment.

Referring to FIG. 11B, the first semiconductor chip 30 and the second semiconductor chip 40 form a bonded structure in the same manner as in the third embodiment. Once the polar liquid 11 is removed from the interface between the pair of the first semiconductor chip 30 and the second semiconductor chip 40, the bonding of the pair of the first and second semiconductor chips (30, 40) is complete.

Referring to FIG. 12A, a tenth exemplary semiconductor structure according to a tenth embodiment of the present invention is shown. According to the tenth embodiment, a first semiconductor chip 30 is provided as a single semiconductor chip in the same manner as in the ninth embodiment.

The first semiconductor chip 30 of the tenth embodiment has the same features as a first semiconductor chip 10 of the third and fourth embodiments except that the first semiconductor chip 30 of the tenth embodiment is an isolated single semiconductor chip. The second semiconductor chip 40 of the tenth embodiment is the same as the second semiconductor chip 40 of the fourth embodiment. The same processing steps are employed as in the fourth embodiment to apply the polar liquid 11. The polar liquid 11 may be the same as in the first embodiment.

Referring to FIG. 12B, the first semiconductor chip 30 and the second semiconductor chip 40 form a bonded structure in the same manner as in the fourth embodiment. Once the polar liquid 11 is removed from the interface between the pair of the first semiconductor chip 30 and the second semiconductor chip 40, the bonding of the pair of the first and second semiconductor chips (30, 40) is complete.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims. For example, three or more chips could be stacked using this invention and/or through silicon vias could be used to connect the chips.

What is claimed is:

1. A method of forming a semiconductor structure comprising:
providing a first semiconductor chip including a mesa and a first recessed peripheral region around said mesa, wherein said mesa has a first hydrophilic top surface, and wherein a first periphery of said mesa has a first shape;
providing a second semiconductor chip having a second hydrophilic top surface, wherein a second periphery of said second hydrophilic top surface has a second shape, and wherein said second shape is a mirror image of said first shape;
applying a polar liquid to said first hydrophilic top surface, wherein an extent of said polar liquid is bounded by said first shape; and
placing said second semiconductor chip on said polar liquid, wherein said polar liquid wets said second hydrophilic top surface, wherein said first periphery is self-aligned to said second periphery.

2. The method of claim 1, wherein said second semiconductor chip includes another mesa and a second recessed peripheral region around said other mesa, wherein said other mesa has said second hydrophilic top surface, and wherein a periphery of said mesa is said second periphery having said second shape.

3. The method of claim 1, wherein said second semiconductor chip includes said second hydrophilic top surface and a hydrophobic top surface, wherein said second hydrophilic top surface has said second periphery, and wherein said hydrophobic top surface laterally abuts and laterally surrounds said second periphery.

4. The method of claim 3, wherein said second hydrophilic top surface and said hydrophobic top surface are substantially coplanar.

5. The method of claim 1, wherein said first hydrophilic top surface includes a first array of top surfaces of first conductive contact structures, and wherein said second hydrophilic top surface includes a second array of top surfaces of second conducive contact structures.

6. The method of claim 5, wherein an entirety of said first hydrophilic top surface is planar, wherein an entirety of said second hydrophilic top surface is planar, and wherein said second array is a mirror image of said first array.

7. The method of claim 1, wherein said polar liquid is selected from pH-neutral water, an acidic solution, a base solution, a hydrogen-peroxide-containing water solution, acetone, methanol, and hydrocarbon based polar liquids.

8. The method of claim 1, wherein said first semiconductor chip is embedded in a substrate of integral and unitary construction and including a plurality of semiconductor chips, and wherein said method further includes:
bonding said second semiconductor chip with said first semiconductor chip; and
dicing said first semiconductor chip from other portions of said substrate.

9. The method of claim 1, wherein said first semiconductor chip is a single semiconductor chip that is not adjoined to another semiconductor chip prior to application of said polar liquid.

10. The method of claim 1, further comprising depositing a material layer around an interface between said first semiconductor chip and said second semiconductor chip, wherein said material layer provides a hermetic seal between said first and second semiconductor chips.

11. A method of forming a semiconductor structure comprising:
providing a first semiconductor chip including a first hydrophilic top surface and a first hydrophobic top surface, wherein said first hydrophilic top surface has a first periphery having a first shape, and wherein said first hydrophobic top surface laterally abuts and laterally surrounds said first periphery;
providing a second semiconductor chip having a second hydrophilic top surface, wherein a second periphery of said second hydrophilic top surface has a second shape, and wherein said second shape is a mirror image of said first shape;
applying a polar liquid to said first hydrophilic top surface, wherein an extent of said polar liquid is bounded by said first shape; and
placing said second semiconductor chip on said polar liquid, wherein said polar liquid wets said second hydrophilic top surface, and wherein said first periphery is self-aligned to said second periphery.

12. The method of claim 11, wherein said second semiconductor chip includes a mesa and a recessed peripheral region around said mesa, wherein said mesa has said second hydrophilic top surface, and wherein a periphery of said mesa is said second periphery having said second shape.

13. The method of claim 11, wherein said second semiconductor chip includes said second hydrophilic top surface and a second hydrophobic top surface, wherein said second hydrophilic top surface has said second periphery, and wherein said second hydrophobic top surface laterally abuts and laterally surrounds said second periphery.

14. The method of claim 13, wherein said second hydrophilic top surface and said second hydrophobic top surface are substantially coplanar.

15. The method of claim 11, wherein said first hydrophilic top surface includes a first array of top surfaces of first conductive contact structures, and wherein said second hydrophilic top surface includes a second array of top surfaces of second conducive contact structures.

16. The method of claim 15, wherein an entirety of said first hydrophilic top surface is planar, wherein an entirety of said second hydrophilic top surface is planar, and wherein said second array is a mirror image of said first array.

17. The method of claim 11, wherein said polar liquid is selected from pH-neutral water, an acidic solution, a base solution, a hydrogen-peroxide-containing water solution, acetone, methanol, and hydrocarbon based polar liquids.

18. The method of claim 11, wherein said first semiconductor chip is embedded in a substrate of integral and unitary construction and including a plurality of semiconductor chips, and wherein said method further includes:
bonding said second semiconductor chip with said first semiconductor chip; and
dicing said first semiconductor chip from other portions of said substrate.

19. The method of claim 11, wherein said first semiconductor chip is a single semiconductor chip that is not adjoined to another semiconductor chip prior to application of said polar liquid.

20. The method of claim 11, further comprising depositing a material layer around an interface between said first semiconductor chip and said second semiconductor chip, wherein said material layer provides a hermetic seal between said first and second semiconductor chips.
